(19) United States
(12) Patent Application Publication
(10) Pub. No.: US 2015/0249426 A1
(43) Pub. Date: Sep. 3, 2015

(54) PHOTOVOLTAIC MODULE JUNCTION BOX

(71) Applicants: David Okawa, San Bruno, CA (US); Sunny Sethi, San Bruno, CA (US); Sy Olson, Oakland, CA (US)

(72) Inventors: David Okawa, San Bruno, CA (US); Sunny Sethi, San Bruno, CA (US); Sy Olson, Oakland, CA (US)

(21) Appl. No.: 14/194,035

(22) Filed: Feb. 28, 2014

(51) Int. Cl. H02S 40/34; H01L 31/052; H02G 3/16

(52) U.S. Cl. CPC H02S 40/34; H02G 3/16; H01L 31/052

(57) ABSTRACT

A junction box for a photovoltaic module can include an angled interface that is configured to couple solar cells to an external component (e.g., another junction box, inverter, etc.). In some embodiments, the angled interface is integrated into the housing of the junction box.

### BACKGROUND

Photovoltaic (PV) cells, commonly known as solar cells, are well known devices for conversion of solar radiation into electrical energy. Generally, solar radiation impinging on the surface of, and entering into, the substrate of a solar cell creates electron and hole pairs in the bulk of the substrate. The electron and hole pairs migrate to p-doped and n-doped regions in the substrate, thereby creating a voltage differential between the doped regions. The doped regions are connected to the conductive regions on the solar cell to direct an electrical current from the cell to an external circuit. When PV cells are combined in an array such as a PV module, the electrical energy collect from all of the PV cells can be combined in series and parallel arrangements to provide power with a certain voltage and current.

A junction box (JBox) can provide an electrical connection from a PV module to an electrical circuit, such as another PV module, or an inverter, among other examples. To protect the electrical connection from the PV cells to the junction box, the junction box can include an environmental barrier, such as a water-proof attachment system to protect the wires connecting to the solar cells. The environmental barrier can help ensure safety and long term reliability of the solar cells.

### BRIEF DESCRIPTION OF THE DRAWINGS

FIG. 1 illustrates an example junction box, according to some embodiments.

FIGS. 2 and 3 illustrate profile and top down views, respectively, of an example arrangement of two junction boxes, according to some embodiments.

FIGS. 4 and 5 illustrate profile and top down views, respectively, of another example arrangement of two junction boxes, according to some embodiments.

FIG. 6 illustrates another example arrangement of two junction boxes, according to some embodiments.

FIGS. 7 and 8 illustrate different views of an example junction box, according to some embodiments.

FIG. 9 illustrates an example junction box, according to some embodiments.

### DETAILED DESCRIPTION

The following detailed description is merely illustrative in nature and is not intended to limit the embodiments of the subject matter of the application or uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” junction box does not necessarily imply that this junction box is the first junction box in a sequence; instead the term “first” is used to differentiate this junction box from another junction box (e.g., a “second” junction box).

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In the following description, numerous specific details are set forth, such as specific operations, in order to provide a thorough understanding of embodiments of the present disclosure. It will be apparent to one skilled in the art that embodiments of the present disclosure may be practiced without these specific details. In other instances, well-known techniques are not described in detail in order to not unnecessarily obscure embodiments of the present disclosure.

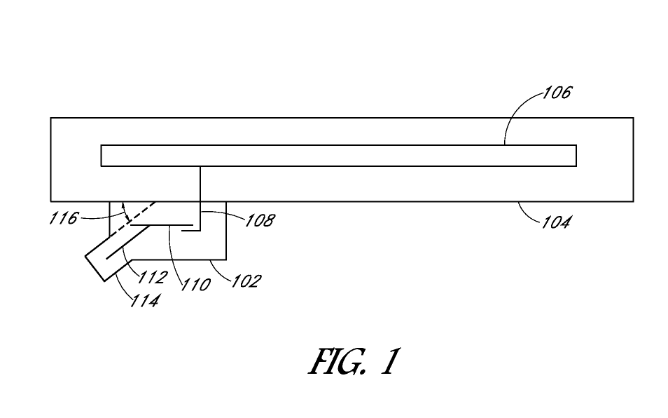

Turning now to FIG. 1, a side view of an example junction box is shown, according to one embodiment. As illustrated in FIG. 1, junction box 102 can be coupled to photovoltaic (PV) laminate 104. For example, in some embodiments, junction box 102 can be mechanically coupled to the backsheet of PV laminate 104 or to a frame of a PV module, such that junction box is positioned on the backside (side facing away from the sun during normal operation) of PV laminate 104. For embodiments in which junction box 102 is coupled to PV laminate 104, the junction box can be attached with an adhesive/pottant that permits adequate contact between the laminate and mounting surface of the junction box and also prevents water seepage.

As shown, PV laminate 104 can include a number of PV cells 106. PV Cells 106 can be arranged in series and/or parallel and then electrically coupled to junction box 102. PV laminate 104 can include one or more encapsulant layers that surround and enclose the PV cells. A cover (e.g., glass or some other transparent or substantially transparent material) can be laminated to the encapsulant layers. The laminate can have a backsheet that is the backmost layer of the laminate and provides a weatherproof and electrically insulating layer that protects the rest of the laminate. The backsheet can be a polymer sheet, and can be laminated to the encapsulant layer(s) of the laminate, or it can be integral with one of the encapsulant layers.

In one embodiment, the PV cells are electrically coupled to junction box 102 via copper ribbons, such as bus bar 108. For example, bus bar 108 can penetrate the backsheet such that the bus bar 108 can be accessed and coupled to junction box 102. Although only one bus bar 108 is shown in FIG. 1, in other embodiments, multiple bus bars can be used to connect the PV cells to the junction box. In various embodiments, one or more bypass diodes can be positioned between the bus bars.

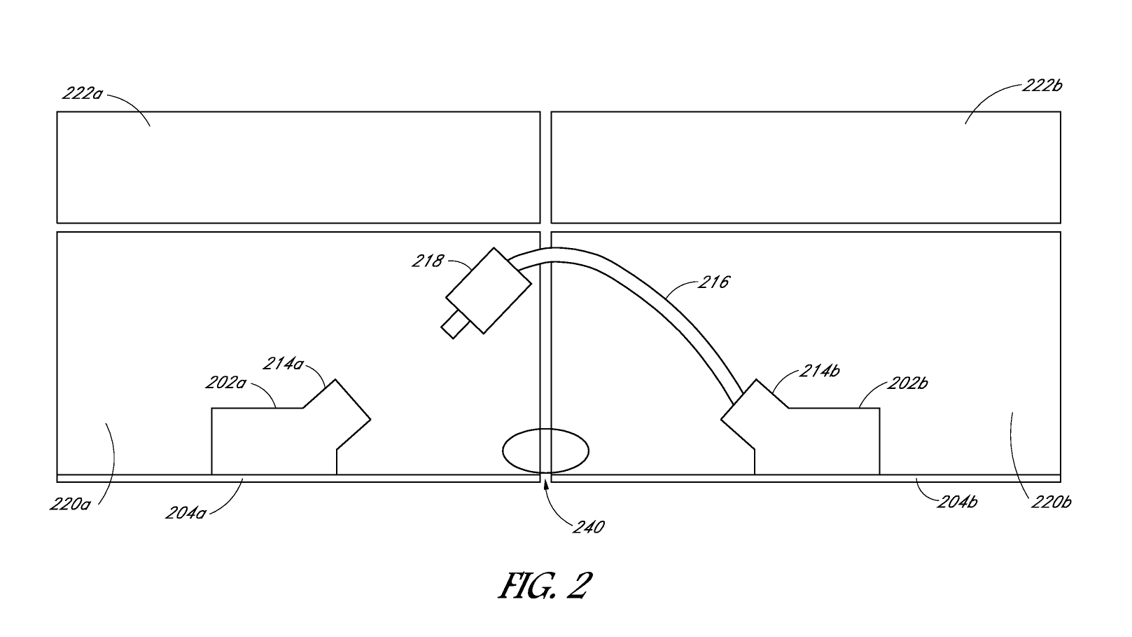

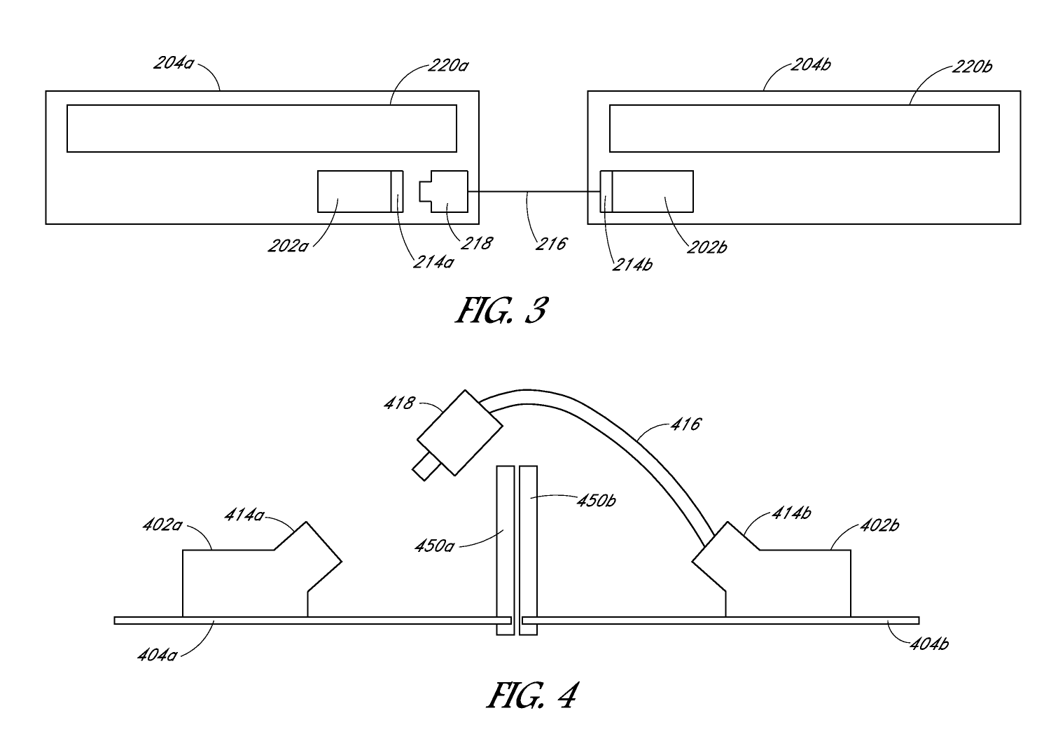

In various embodiments, PV laminate 104 can be coupled to a frame (e.g., as shown in FIG. 4) to form a PV module or it can be coupled to a mirror in a concentrated PV system (e.g., as shown in FIG. 2). The PV module has a front side that faces the sun during normal operation and a back side opposite the front side.

Junction box 102 can be coupled to an inverter (whether a microinverter mounted to the module or a remotely located inverter) to convert direct current (DC) power to alternating current (AC) power, to another junction box in series to combine power from multiple PV laminates, power collection devices, power storage devices, among other electrical systems.

Typical junction boxes utilize a long flexible cable coming straight out of the side of the junction box which is then coupled a flexible cable coming straight out of the side of another junction box. Long flexible cables allow for easy connection and account for structural tolerances (e.g., clear the frame of a PV module). If the flexible cables are too long, however, the cables can protrude from behind the receiver surface which can necessitate additional components to control the cable locations, which can then lead to increased system costs. In large scale applications, the increased system costs can be significant. In a concentrated photovoltaic system, long flexible cables coming straight from the side of junction boxes can be problematic as the straight connection from one junction box to another can be exposed to a concentrated beam region (as shown in FIG. 2 as concentrated beam region 240) of light. Exposure to the concentrated beam poses a risk for wire burning, which in turn can render the system inoperable and/or pose safety (e.g. equipment or personal) risks.

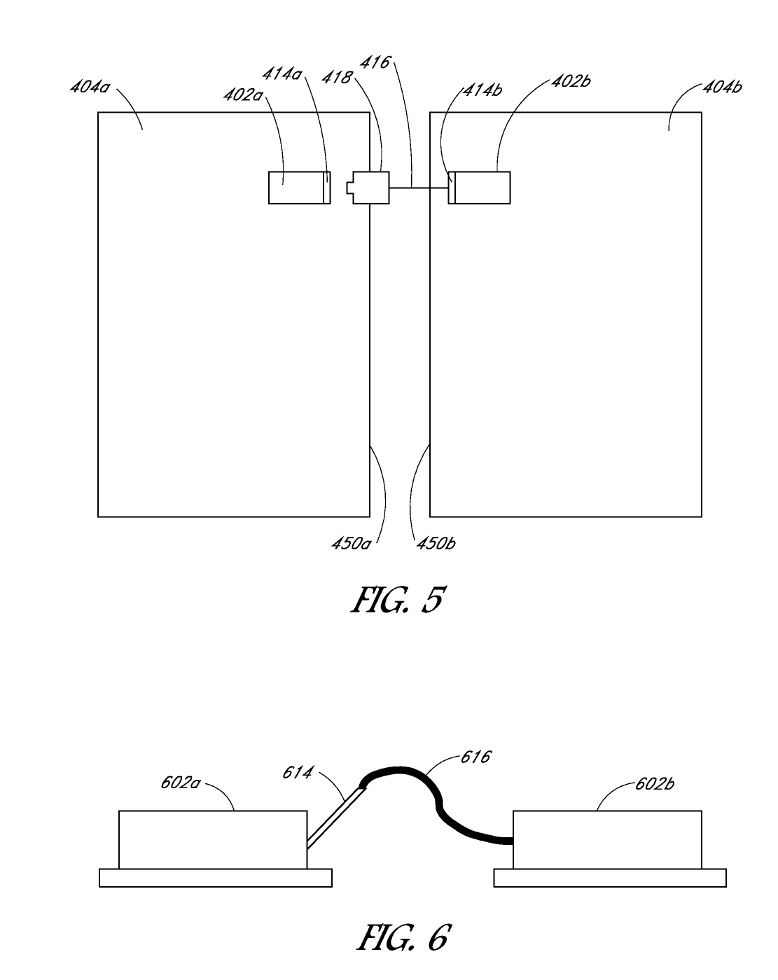

To address some of the issues, in one embodiment, a junction box can include angled interface 114. Bus bar 108 can be coupled to connector tab 110, which is then coupled to conductor 112 of angled interface 114. As illustrated, angled interface 114 is at a non-zero angle 116 relative to the mounting surface of junction box 102 (or thought of from the perspective of the laminate) relative to PV laminate 104. Examples of non-zero angle 116 can include 10 degrees, 15 degrees, 45 degrees, 75 degrees, or 90 degrees, among others. The angle used can depend on a variety of factors, such as thickness of the frame, distance between receivers/PV laminates, thickness of the cable, orientation on the PV laminate/receiver, among other factors. Although the angled interface is shown in the corner of junction box 102 (where the side of the junction box meets the surface opposite the mounting surface), in other embodiments, the angled interface can be on the side of the junction box (as shown in FIG. 6) or on the surface of the junction box opposite the mounting surface (not illustrated). Moreover, in a particular system, different angles can be used for different junction boxes. For instance, one junction box can have an angled interface at 15 degrees and can be coupled to another junction without an angled interface (straight interface) or with an angled interface at 30 degrees.

In various embodiments, the junction box, specifically the angled interface of the junction box, includes a connector directly integrated or attached to the junction box housing. A junction box having an integrated connector is referred to herein as a connectorized junction box. In other embodiments, the angled interface of the junction box does not include an integrated connector and includes an attached flexible cable with a connector on the end of the flexible cable. Such a junction box is referred to herein as a cabled junction box. Moreover, in some systems, for example as shown in FIGS. 2, 4, and 6, one connectorized junction box can be used in conjunction with (e.g., coupled to) a cabled junction box. As described in more detail below, using a connectorized junction box in conjunction with a cabled junction box can result in a parts reduction over systems that include only connectorized junction boxes or only cabled junction boxes. Because junction boxes need to provide a robust water-proof structure, reducing the number of parts can reduce the number of seals and joints that must provide robust water protection thereby reducing the likelihood of water entering the junction box.

Further, although the examples illustrated herein show an angled interface that protrudes from the junction box, in some embodiments, the angled connectorized connection may be flush with one or more edges of the junction box. Additionally, although the examples illustrate the angled interface being angled in a single plane, the angled interface may be angled in multiple planes for greater flexibility. For example, the angled interface can be angled relative to the mounting surface of the junction box in an x-plane as well as in a y-plane.

Moreover, in some embodiments, a junction box having an angled interface can be coupled to a junction box without the angled interface. Accordingly, a solar installation can include any combination of angled interface junction boxes, straight interface (non-angled) junction boxes, connectorized junction boxes, and/or cabled junction boxes.

Although FIG. 1 depicts a single pole junction box, in other embodiments, a dual pole junction box can include the same features described at FIG. 1. Moreover, although the Figures described herein only illustrate a single junction box per PV laminate, in some embodiments, a PV laminate may include multiple junction boxes (e.g., multiple single pole junction boxes).

The disclosed junction box having an angled connector can offer many advantages. For example, the angled connector can allow for easy attachment and detachment of the junction box thereby resulting in reduced connection time as compared to other junction boxes. Such reduced connection time can result in magnitudes of time savings for large scale system installation, such as in utility scale solar farms.

Additionally, the angled connector can allow for a shorter cable length compared to other junction boxes that require a cable with a greater amount of slack to accommodate structural tolerances. This results in reduced cost and series resistance losses for the PV system. And, as noted herein, reduced cable length also removes the need for additional components to control the excess cable slack.

The disclosed junction box and systems also permit a lower number of gaskets than in convention junction box systems. For example, in one embodiment, only three sealing interfaces exist as opposed to five sealing interfaces in other systems. A lower number of gaskets presents fewer failure point locations for water to creep into the junction box assembly thereby reducing the risk of failure. Further, the angled connector can allow water to flow away from joints and connections thereby reducing the likelihood of water seepage into the junction box.

Angled connectors can also provide for a more controlled wire management system. As described herein, in some concentrated PV systems, cables can reside in the path of concentrated light, which can lead to burning or melting wires or connectors, which can lead to exposed live wires or even making connectors or wires inoperable. Not only can such failure affect power production, but it can also lead to safety risk (e.g., safety of PV system, personal safety, etc.). By reducing wire length as a result of using the angled connector, additional cable management solutions (and their additional cost in parts and/or labor to install) can be avoided or reduced. This is b/c of the rigid nature of the wires at these lengths as well as b/c they no longer have the heavy connectors hanging in between wires (in the connectorized/unconnectorized combo—not sure if that needs to be spelled out)

Turning now to FIGS. 2 and 3, a profile view and top view, respectively, of an example arrangement of two junction boxes in a concentrated PV system is illustrated, according to some embodiments. As shown, junction box 202a having angled interface 214a is coupled to the back side (side facing away from the sun during normal operation) of PV laminate 204a. Note that PV laminate 204a may also be referred to as a receiver. Also coupled to PV laminate 204a is heat sink 220a. The heat sink, receiver, and junction box combination is then mechanically coupled to a back surface (non-reflective surface) of concentrating mirror 222a. Not shown, the front surface (reflective surface) of another concentrating mirror (other than mirrors 222a and 222b) may be configured to reflect light onto PV laminate 204a. In some embodiments, the heat sink, received, and junction box combination can be mechanically coupled to a non-mirror mounting surface.

The example of FIG. 2 also includes junction box 204b having angled interface 214b, which is coupled to the back side of PV laminate 204b. Also coupled to PV laminate 204b is heat sink 220b. The heat sink, receiver, and junction box combination is then mechanically coupled to a back surface (non-reflective surface) of concentrating mirror 222b.

As shown, junction box 202a is a connectorized junction box having an integrated female connector. The integrated female connector is configured to receive male connector 218 from cable 216 of cabled junction box 202b. Use of angled interfaces/connectors can permit cable 216 and connector 218 to avoid concentrated beam region 240 and therefore reduce risk of damage to the cable or connector as opposed to a system without angled interfaces.

Turning now to FIGS. 4 and 5, a profile view and top view, respectively, of an example arrangement of two junction boxes in a one sun (non-concentrating) PV system is illustrated, according to some embodiments. As shown, junction box 402a having angled interface 414a is coupled to the back side (side facing away from the sun during normal operation) of PV laminate 404a. Also coupled to PV laminate 404a is frame 450a, although note that, in some embodiments, junction box 402a can be coupled directly to frame 450a.

Similarly, junction box 402b having angled interface 414b is coupled to the back side of PV laminate 404b. Also coupled to PV laminate 404b is frame 450b, although note that, in some embodiments, junction box 402b can be coupled directly to frame 450b.

As illustrated in FIGS. 4 and 5, using junction boxes with an angled interface can reduce the length of cable needed to connect the junction boxes and therefore reduce cost and the need for additional cable management components.

Although FIGS. 2-5 show a female connectorized junction box and a male connector for a cabled junction box, the connectorized junction box can alternatively be a male connectorized junction box that is configured to receive a female connector from a cabled junction box.

Moreover, although the examples of FIGS. 2-5 illustrate a connectorized junction box configured for use with a cabled junction box, in other embodiments, two connectorized junction boxes or two cabled junction boxes can be used together, whether with angled interfaces, or straight interfaces.

Further, although the angles of the angled interfaces of the junction box pairs in FIGS. 2-5 are shown as the same angle, in other embodiments, the angled interface for a first junction box could be one angle (e.g., 15 degrees) and the angled interface for a second junction box coupled to the first junction box could be a second, different angle (e.g., 30 degrees).

FIG. 6 illustrates another example pair of junction boxes, according to some embodiments. Specifically, FIG. 6 is similar to the junction box arrangement in FIGS. 2-5 except that angled interface 614 protrudes from the side of junction box housing 602a rather than from a corner of the junction box housing as was the case in FIGS. 1-5. Additionally, cabled junction box 602b does not have an angled interface. Instead, cable 616 leaves junction box 602b straight and not at an angle.

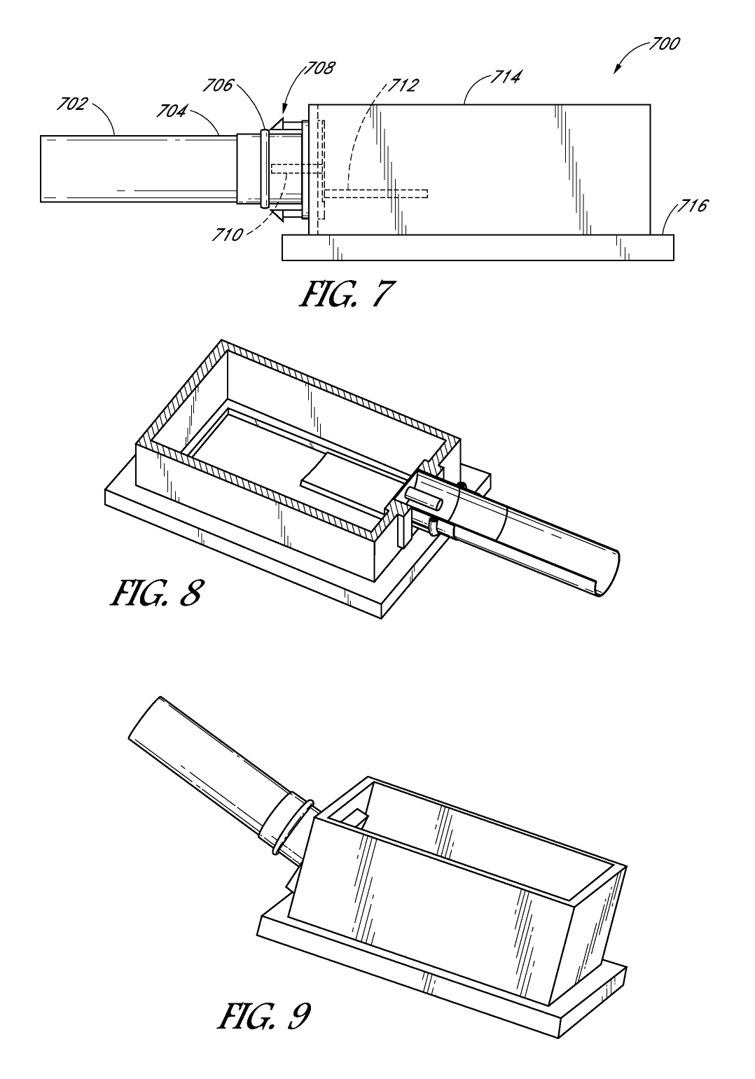

FIGS. 7 and 8 illustrate side and cross-section views, respectively, of an example connectorized junction box, according to some embodiments. Although FIGS. 7 and 8 do not show an angled interface, the components illustrated in FIGS. 7 and 8 apply equally to the junction boxes having an angled interface disclosed herein. As illustrated, junction box 700 includes alignment system 702 that is configured to align the connection from junction box 700 to another component (e.g., another junction box, inverter, etc.). Inner gasket 704 is coupled to alignment system 702 and outer gasket 706. In some embodiments, alignment system 702, inner gasket 704, and outer gasket 706 are part of a connector that couples to a connectorized junction box and are not components of the actual junction box. Aligning/locking pins 708 are part of a female connectorized portion of junction box 700 and are configured to receive a male connector. Note that in other embodiments, a male connectorized portion can be used, which is configured to receive a female connector from a cable. Metal pin 710 can be used to align the connector with the connectorized portion of the junction box. In the illustrated embodiment, bus bar soldering plate 712 couples the connector to the solar cells of a PV laminate. Housing 714 can be made of plastic or another material and base 716 is configured to couple to a PV laminate and/or frame coupled to a PV laminate. FIG. 8 illustrates a cross-sectional view of the junction box of FIG. 7 to better illustrate internal components (e.g., metal pin, bus bar soldering plate, etc.) and their geometry. Similar to FIG. 8, FIG. 9 illustrates a cross-sectional view of a junction box having an angled connector. The components described at FIG. 7 apply equally to the junction box of FIG. 9.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A photovoltaic system, comprising:
a first photovoltaic laminate; and
a first junction box coupled to the first photovoltaic laminate, wherein the first junction box includes a first electrical interface at a first non-zero angle relative to the first photovoltaic laminate.

2. The photovoltaic system of claim 1, wherein the first junction box further includes a housing that houses a connection between a plurality of photovoltaic cells of the first photovoltaic laminate and the first electrical interface.

3. The photovoltaic system of claim 2, wherein the first electrical interface includes a first connector configured to couple to a second connector, wherein the first connector is integrated into the housing.

4. The photovoltaic system of claim 3, wherein the first connector is a female connector and the second connector is a male connector.

5. The photovoltaic system of claim 2, wherein the first electrical interface includes a cable integrated into the housing and a connector coupled to an end of the cable.

6. The photovoltaic system of claim 1, further comprising:
a second photovoltaic laminate; and
a second junction box coupled to the second photovoltaic laminate, wherein the second junction box includes a second electrical interface at a second non-zero angle relative to the second photovoltaic laminate,
wherein the first electrical interface is coupled to the second electrical interface.

7. The photovoltaic system of claim 6, wherein the first non-zero angle is the same as the second non-zero angle.

8. The photovoltaic system of claim 6, wherein the first electrical interface includes a first connector integrated into a housing of the first junction box, wherein the second electrical interface includes a cable integrated into a housing of the second junction box and a second connector at an end of the cable, wherein the first connector is coupled to the second connector.

9. The photovoltaic system of claim 1, further comprising:
a second junction box coupled to the first photovoltaic laminate, wherein the second junction box includes a second electrical interface at a second non-zero angle relative to the first photovoltaic laminate.

10. The photovoltaic system of claim 1, further comprising:
a heat sink coupled to the photovoltaic laminate and adjacent to the first junction box; and
a mirror configured to direct light onto the photovoltaic laminate.

11. The photovoltaic system of claim 1, wherein the first junction box is a single pole junction box.

12. The photovoltaic system of claim 1, wherein the first non-zero angle is greater than approximately 15 degrees.

13. The photovoltaic system of claim 1, further comprising:
an inverter coupled to the first electrical interface, wherein the inverter is configured to receive direct current from the first photovoltaic laminate and to convert the direct current to alternating current.

14. A junction box for a photovoltaic module, comprising:
a housing having a bottom portion for coupling the junction box to a photovoltaic laminate, and an angled interface; and
the angled interface configured to electrically couple a plurality of solar cells to an external component, wherein the angled interface is oriented at a non-zero angle relative to the bottom portion.

15. The junction box of claim 14, wherein the external component is another junction box for another photovoltaic module, wherein the other junction box also includes a respective angled interface oriented at the non-zero angle.

16. The junction box of claim 14, wherein the external component is an inverter configured to convert direct current from the plurality of solar cells to alternating current.

17. The junction box of claim 14, wherein the angled interface includes a connector integrated into the housing.

18. The junction box of claim 17, wherein the connector is a female connector.

19. The junction box of claim 14, wherein the angled interface includes a cable integrated into the housing and a connector attached to the cable.

20. A photovoltaic system, comprising:
first and second photovoltaic laminates;
a first junction box coupled to the first photovoltaic laminate, wherein the first junction box includes a first angled interface at a first non-zero angle relative to the first photovoltaic laminate; and
a second junction box coupled to the second photovoltaic laminate, wherein the second junction box includes a second angled interface at a second non-zero angle relative to the second photovoltaic laminate.
